(19) United States
(12) Patent Application Publication
(10) Pub. No.: US 2009/0253268 A1
(43) Pub. Date: Oct. 8, 2009

(54) POST-CONTACT OPENING ETCHANTS FOR POST-CONTACT ETCH CLEANS AND METHODS FOR FABRICATING THE SAME

(75) Inventors: Deborah Yellowaga, Chandler, AZ (US); John A. McFarland, Scottsdale, AZ (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL, INC., Morristown, NJ (US)

(21) Appl. No.: 12/062,126

(22) Filed: Apr. 3, 2008

(51) Int. Cl. C09K 13/00; H01L 21/302

(52) U.S. Cl. 438/753; 252/79.1; 257/E21.214

(57) ABSTRACT

Post-contact opening etchants for post-etch cleans and methods for fabricating such etchants are provided. In an exemplary embodiment, a post-contact opening etchant comprises anhydrous hydrogen fluoride and a fluoride-dissociation modulating agent. In another embodiment, a method for fabricating a post-contact opening etchant comprises providing anhydrous hydrogen fluoride, combining the anhydrous hydrogen fluoride and a fluoride-dissociation modulating agent, and mixing the anhydrous hydrogen fluoride and the fluoride-dissociation modulating agent to form a homogeneous mixture.

### FIELD OF THE INVENTION

The present invention generally relates to etchants and methods for fabricating etchants, and more particularly relates to post-contact opening etchants for post-contact etch cleans and methods for fabricating such etchants.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). As illustrated in FIG. 1, an MOS transistor 20 includes a gate electrode 22 as a control electrode that is formed overlying a semiconductor substrate 24 and between spaced-apart source and drain regions 26 that are formed within the semiconductor substrate and between which a current can flow. A control voltage applied to the gate electrode controls the flow of current through a channel 28 in the semiconductor substrate between the source and drain regions and beneath the gate electrode.

The gate electrode of the MOS transistor is accessed via a conductive contact (not shown) typically formed on the gate electrode. The conductive contact is usually formed by depositing an insulating layer or gettering layer 30 over the gate electrode and etching a contact opening 32 in the insulating layer. The contact opening then is filled by metals or metal alloys to form the conductive contact to the gate electrode. Conductive contacts also may be formed to electrically contact other silicon-comprising elements, such as the source and drain regions 26.

Between the etching of the insulating layer to form the contact openings and the deposition of the metals to form the conductive contacts, a residue may form on the exposed surface 34 of the gate electrode or other silicon-comprising elements. The residue may comprise oxides, such as silicon oxides and metal oxides, and organic contaminants. It is desirable to remove this residue before formation of the conductive contact to enhance conduction between the contact and the gate electrode (and/or other silicon-comprising elements). Typically, an etchant or cleaner (herein referred to collectively as “etchant”) comprising aqueous hydrogen fluoride, that is, an etchant or cleaner comprising hydrogen fluoride and at least 49 weight percent (wt. %) water, is used to etch the residue. However, gate electrodes often are fabricated from polycrystalline silicon and, accordingly, the insulating layer 30 typically is doped with mobile ionic species such as boron, phosphorous, or a combination thereof to prevent metals from diffusing to and poisoning the gate electrode. The insulating layer may even be formed from a tri-layer of materials comprising, for example, boron-phosphorous doped silicon dioxide 36, phosphorous-doped silicon dioxide 38, and/or a low dielectric constant (“low k”) material 40, which materials may be present in any suitable order. The doping of such insulating materials causes them to be much more susceptible to etching by hydrogen fluoride. In this regard, the insulating materials tend to etch faster than the residue, thus resulting in a widening of the contact opening 32. In addition, when different insulating layers are present, they can be etched at different rates by the etchant, thus resulting in a non-uniform profile of the contact opening. There is a continuing trend to incorporate more and more circuitry on a single IC chip and, accordingly, the size of each individual device in the circuit and the size and spacing between device elements must decrease. Thus, there is little or no tolerance for the widening of contact openings during removal of the residue and for odd-shaped contact openings.

Accordingly, it is desirable to provide improved post-contact opening etchants for post-contact etch cleans. It also is desirable to provide post-contact opening etchants that result in etch rates of doped insulating layers that are equal to or slower than etch rates of residue on silicon-comprising surfaces. It is further desirable to provide post-contact opening etchants that result in etch rates of doped insulating layers that substantially maintain the uniformity of the contact opening profile. In addition, it is desirable to provide methods for fabricating such post-contact opening etchants. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A post-contact opening etchant is provided in accordance with an exemplary embodiment of the present invention. The post-contact opening etchant comprises anhydrous hydrogen fluoride and a fluoride-dissociation modulating agent.

A method for fabricating a post-contact opening etchant is provided in accordance with another exemplary embodiment of the present invention. The method comprises the steps of providing an anhydrous hydrogen fluoride, combining the anhydrous hydrogen fluoride and a fluoride-dissociation modulating agent, and mixing the anhydrous hydrogen fluoride and the fluoride-dissociation modulating agent to form a homogeneous mixture.

A method is provided for cleaning a silicon-comprising surface of a semiconductor device. The method comprises applying an etchant to the silicon-comprising surface, wherein the etchant comprises hydrogen fluoride and a fluoride-dissociation modulating agent. The silicon-comprising surface is exposed to the etchant for a predetermined time period, and is removed from the silicon-comprising surface.

### BRIEF DESCRIPTION OF THE DRAWINGS

The present invention will hereinafter be described in conjunction with the following drawing figures, wherein like numerals denote like elements, and wherein:

FIG. 1 is a cross-sectional view of a conventional MOS transistor;

FIG. 2 is a flow chart illustrating a method for fabricating a post-contact opening etchant, in accordance with an exemplary embodiment of the present invention; and

FIG. 3 is a flow chart illustrating a method for using a post-contact opening etchant, in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

In accordance with an exemplary embodiment of the present invention, post-contact opening etchants are provided for the removal of residual oxide and organic residues that form on polycrystalline silicon gate electrodes and other silicon-comprising surfaces after formation of a contact opening thereto through one or more insulating materials, such as, for example, impurity-doped insulating materials. The impurity-doped insulating materials may be doped with conductivity-determining type impurities known in the semiconductor arts, such as boron and phosphorous, and may include boron-doped silicon dioxide (also known as boron-doped silicate glass (BSG)), phosphorous-doped silicon dioxide (also known as phosphorous-doped silicate glass (PSG)), boron-phosphorous-doped silicon dioxide (also known as boron-phosphorous-doped silicate glass (BPSG)), and the like. The post-contact opening etchants are formulated to control the dissociation of hydrogen fluoride. In this regard, the doped insulating materials are etched at the same etch rate or at a slower etch rate than the residual oxides, thus minimizing the widening of the contact openings in the insulating materials. In addition, the etchants are relatively non-selective with respect to different doped insulating materials exposed by the contact opening. Accordingly, uniformity of the contact opening profile is substantially maintained.

In accordance with one exemplary embodiment of the invention, a post-contact opening etchant comprises hydrogen fluoride and at least one fluoride-dissociation modulating agent. Hydrogen fluoride tends to disassociate, with the fluoride ion being the active etchant component. Without wishing to be bound by theory, it is believed that the fluoride-dissociation modulating agent bonds with the hydrogen fluoride through hydrogen bonding and causes the hydrogen fluoride to dissociate to a greater extent than it typically would dissociate in water. In this regard, the etchant is less selective with respect to the different doped insulating materials exposed by the contact opening so that it etches the materials at more similar rates than if the fluoride-dissociation modulating agent was not present. In addition, the etchant etches the residue at an etch rate faster than or equal to the etch rates of the doped insulating materials. In one exemplary embodiment, the etchant etches the residue at an etch rate of about 0.5 to about 1 nanometers (nm)/minute (min). In another exemplary embodiment, the etchant etches the residue at etch rates substantially equal to the etch rates of the doped insulating material(s). In a preferred exemplary embodiment, the etchant etches the residue at an etch rate that is at least about 1.2 times faster than the etch rates of the doped insulating materials.

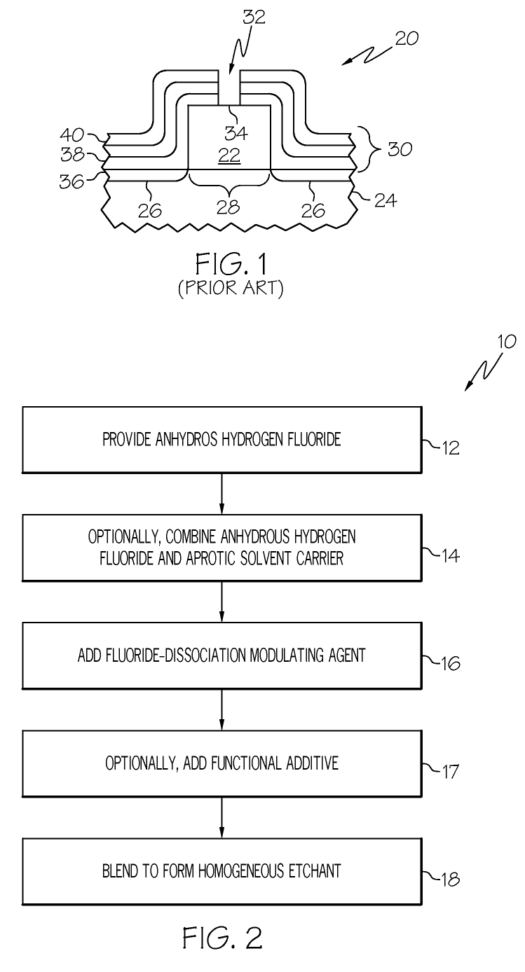

FIG. 2 illustrates a method 10 for fabricating a post-contact opening etchant in accordance with an exemplary embodiment of the present invention. The method 10 begins with the step of providing anhydrous hydrogen fluoride (step 12). As used herein, the term “anhydrous hydrogen fluoride” means hydrogen fluoride with no more than 10 wt. % water and preferably no more than 1 wt. % water. The hydrogen fluoride is provided as an anhydrous gas, liquefied gas (i.e., hydrogen fluoride in a liquid state), or combination of gas and liquefied gas. Examples of anhydrous hydrogen fluoride suitable for forming the post-contact opening etchant include anhydrous hydrogen fluoride 10056274 available from Honeywell International of Morristown, N.J.

In one exemplary, optional embodiment, an aprotic solvent carrier and the anhydrous hydrogen fluoride are combined to form a hydrogen fluoride (HF)/aprotic solvent carrier mixture (step 14). The aprotic solvent carrier comprises one or more aprotic solvents. An aprotic solvent is an organic solvent that does not exchange protons with a substance, such as hydrogen fluoride, dissolved in it. Examples of aprotic solvents suitable for use in the aprotic solvent carrier include propylene carbonate, gamma-butyrolacetone, N-methyl-2-pyrrolidone, ethylene carbonate, butylene carbonate, N,N-dimethylacetamide, propylene glycol monomethyl ether acetate, dimethyl sulfoxide, dimethyl formamide, dimethyl acetamide, and the like. In one exemplary embodiment, the aprotic solvent carrier comprises a mixture of aprotic solvents. In this regard, an aprotic solvent carrier with desired characteristics can be obtained. For example, an aprotic solvent with a low flashpoint but high water solubility may be combined with an aprotic solvent with a high flashpoint but low water solubility to obtain an aprotic solvent carrier that has a high flashpoint and high water solubility so that it is safe to use and can be easily removed with a water rinse after the cleaning process. In a preferred embodiment of the invention, the aprotic solvent carrier comprises propylene carbonate. Propylene carbonate has a relatively high flashpoint and is a class 3B liquid, according to the Occupational and Safety Health Standards of the Occupational and Safety Health Administration (OSHA) standards, 29 C.F.R. 1910.106(a)(18)(ii)(b). In addition, propylene carbonate also can facilitate removal of organic-based residues present on the silicon-comprising surface.

In one exemplary embodiment, the aprotic solvent carrier is placed in an appropriate container and the hydrogen fluoride is bubbled through the solvent carrier. The container can be made of essentially any material appropriate for contact with hydrogen fluoride and free of impurities to guarantee high purity of the resulting etchant. Containers are preferred that have inner walls contacting the aprotic solvent carrier that are made of metal-free polymers such as high-density polyethylene (HDPE), perfluoroalkoxyethylene (PFA), polypropylene, polyvinylidene difluoride (PVDF), and perfluorinated polyethylene propylene (FEP). Unstabilized high density (HD) polyethylenes, such as HD-polyethylenes with a specific density of 0.940-0.970 g/cm³, in particular 0.942-0.961 g/cm³, are among the polymers that are suitable. This includes polyethylenes distributed under the trademark Lupolen®, such as Lupolen® 6021D, Lupolen® 5021D, Lupolen® 4261AQ149, and Lupolene® 4261AQ135. The containers may consist of one or more layers, wherein the one or more external layers that do not contact the aprotic solvent and hydrofluoric acid can be made of essentially any suitable material. The hydrogen fluoride is delivered as a gas and/or liquefied gas to the aprotic solvent in the container until a predetermined amount of hydrogen fluoride is added to the solvent. If, according to an exemplary embodiment of the present invention, the hydrogen fluoride is added to the aprotic solvent carrier in gaseous form as well as in the form of a liquefied gas, the gaseous form may be introduced first followed by the liquefied gas form or, alternatively, the liquefied gas form may be delivered first followed by the gaseous form. It is still further possible to simultaneously introduce gaseous and liquefied hydrogen fluoride. In this regard, the gaseous and liquefied gaseous forms may be delivered separately but substantially simultaneously or the gaseous and liquefied forms can be combined prior to introduction.

It will be appreciated that the hydrogen fluoride and the aprotic solvent carrier can be combined in a variety of suitable manners. For example, the hydrogen fluoride may be added to a first portion of an aprotic solvent carrier to form a concentrate; after addition of the hydrogen fluoride, additional aprotic solvent carrier then may be added to achieve a final predetermined concentration of hydrogen fluoride in the solvent. In another exemplary embodiment, when the aprotic solvent carrier comprises two or more different solvents, the hydrogen fluoride may be added first to one or more of these solvents, followed by the addition of the other solvents.

According to an exemplary embodiment of the present invention, the hydrogen fluoride, introduced as a gas and/or liquefied gas into the aprotic solvent carrier, may be heated or cooled to a predetermined temperature prior to introduction. In another exemplary embodiment of the present invention, the aprotic solvent carrier may be heated or cooled to a predetermined temperature prior to introduction of the hydrogen fluoride. The HF/aprotic solvent carrier mixture also may be heated or cooled to a predetermined temperature during or after introduction of the hydrogen fluoride. The heating or cooling may be performed by conventional means. In a preferred embodiment of the present invention, the hydrogen fluoride is added to the aprotic solvent with both at approximately room temperature (about 15° C. to about 27° C.).

In accordance with another exemplary embodiment of the invention, at least one fluoride-dissociation modulating agent is added to the hydrogen fluoride or, if formed, the HF/aprotic solvent carrier mixture (step 16). Examples of suitable fluoride-dissociation modulating agents include those materials with a lone pair of electrons that can react with the hydrogen of the hydrogen fluoride, such as secondary organic sulfur-comprising materials and tertiary organic phosphorous-comprising compounds, for example triphenylphosphene. In a preferred embodiment of the present invention, the fluoride-dissociation modulating agent is a tertiary organic amine. Examples of tertiary organic amines suitable for addition to the hydrogen fluoride or the HF/aprotic solvent carrier mixture include pyridine, hexamine, triethylamine, trimethylamine, tributylamine, 1,4-diazabicyclo[2.2.2]octane (DABCO), quinuclidine, 1,5-diazabicyclo[4.3.0] non-5-ene (DBN), N-methyl piperidine, N-ethyl piperidine, N-methyl pyrrole, N-ethyl pyrrole, quinoline, pyrimidine, sec-butyldiethylamine, N,N-dimethyl-4-methylaniline, pyrazine, cinnoline, phtalazine, quinazoline, quinoxaline, and the like, and mixtures thereof. It will be understood that, if an HF/aprotic solvent carrier concentrate is first formed, as described above, the fluoride-dissociation modulating agent can be added to the concentrate before the concentrate is diluted with additional solvent or solvent carrier. In addition, it will be understood that, while FIG. 2 illustrates the step of adding the fluoride-dissociation modulating agent after the optional step of combining the gaseous hydrogen fluoride and the aprotic solvent carrier, the step of adding the fluoride-dissociation modulating agent can be performed before the step of adding the gaseous hydrogen fluoride.

According to an exemplary embodiment of the present invention, the fluoride-dissociation modulating agent may be heated or cooled to a predetermined temperature prior to introduction. In another exemplary embodiment of the present invention, the HF/aprotic solvent carrier mixture may be heated or cooled to a predetermined temperature prior to introduction of the fluoride-dissociation modulating agent. The HF/aprotic solvent carrier mixture also may be heated or cooled to a predetermined temperature during or after introduction of the fluoride-dissociation modulating agent. The heating or cooling may be performed by conventional means. In a preferred embodiment of the present invention, the fluoride-dissociation modulating agent is added to the HF/aprotic solvent carrier mixture with both at approximately room temperature (about 15° C. to about 27° C.).

In an exemplary embodiment of the invention, the fluoride-dissociation modulating agent and the hydrogen fluoride are present in the etchant in an amount sufficient to achieve an etch rate of a residue of about 0.5 to about 1 nm/min. In another exemplary embodiment, the fluoride-dissociation modulating agent and the hydrogen fluoride are present in an amount sufficient to achieve an etch rate of the residue that is at least about 1.2 times faster than the etch rates of the doped insulating materials exposed by the contact opening and with the etch rates of the doped insulating materials, if different doped insulating materials are present, being substantially similar. Generally, the concentrations of the hydrogen fluoride and the fluoride-dissociation modulating agent in the solvent carrier are a function of the acid disassociation constant (pKₐ) of the fluoride-dissociation modulating agent. The smaller the pKₐ, the stronger acid the fluoride-dissociation modulating agent is, and the greater the disassociation of the hydrogen fluoride. In one exemplary embodiment, the hydrogen fluoride is present in an amount no greater than about 5 wt % of the fluoride-dissociation modulating agent /HF/aprotic solvent carrier mixture. In another exemplary embodiment, the fluoride-dissociation modulating agent is present in an amount no greater than about 10 wt % of the fluoride-dissociation modulating agent /HF/aprotic solvent carrier mixture.

In addition to the fluoride-dissociation modulating agent, one or more functional additives may be added to the etchant (step 17). For example, the etchant may further comprise one or more surfactants. The surfactants serve to reduce the surface tension of the etchant so that the etchant can easily enter and exit small contact openings. In addition, the etchant may comprise other anhydrous fluoride sources to facilitate etching of the residual oxides and organic residues. Examples of other anhydrous fluoride sources suitable for use in the etchant include ammonium fluoride, tetramethylammonium fluoride, tetrabutylammonium fluoride, tetraethylammonium fluoride, benzyltrimethylammonium fluoride, ammonium bifluoride, and the like, and mixtures thereof. Other additives, such as, for example, wetting agents, miscibility modifiers, and viscosity modifiers, also may be added to the etchant. While FIG. 2 illustrates the step of adding a functional additive being performed after the step of adding the fluoride-dissociation modulating agent, it will be appreciated that the functional additive can be added directly to the anhydrous hydrogen fluoride (step 12), to the aprotic solvent carrier or the HF/aprotic solvent carrier mixture (step 14) or during mixing of the etchant (step 18), discussed in more detail below.

The hydrogen fluoride, the fluoride-dissociation modulating agent, and the aprotic solvent carrier, if present, and any present additives, are mixed using any suitable mixing or stirring process that forms a homogeneous etchant (step 18). For example, a low speed sonicator or a high shear mixing apparatus, such as a homogenizer, a microfluidizer, a cowls blade high shear mixer, an automated media mill, or a ball mill, may be used for several seconds to an hour or more to form the etchant. Heat also may be used to facilitate formation of the etchant. While FIG. 2 illustrates the step of mixing performed after the addition of the fluoride-dissociation modulating agent, the hydrogen fluoride, and the additives to the aprotic solvent carrier, it will be appreciated that the mixing may be performed before, during, and/or after the providing and/or the addition of any of these components.

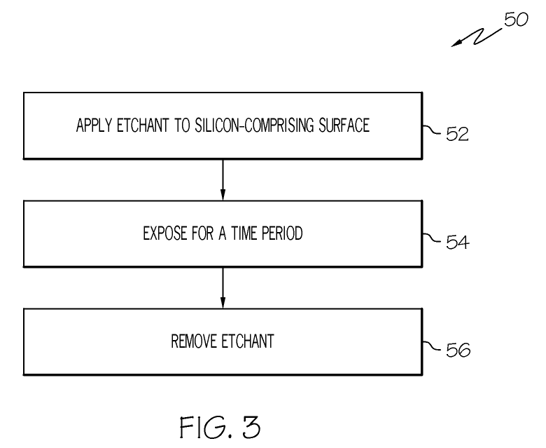

As described above, the resulting etchant can be used to remove residual oxides and organic residues that form on a gate electrode or other silicon-comprising surface of a semiconductor device after the formation of a contact opening thereto through an insulating material. FIG. 3 is a flow chart illustrating a method 50 for utilizing the post-contact opening etchant. The method 50 begins by applying the etchant to the semiconductor device (step 52). The etchant may be applied using any suitable method for applying liquids to semiconductor wafers known in the industry. For example, the semiconductor device may be immersed in a bath of the etchant, with or without agitation or fluid flow, or the etchant may be spun or sprayed onto the semiconductor device. The semiconductor device is exposed to the etchant for a time period sufficient to remove at least substantially all of the residue (step 54). The time the semiconductor device is exposed to the etchant is dependant on the method used to apply the etchant. For example, the wafer may be immersed in a bath of the etchant for about 3 to about 10 minutes, preferably about 3 to about 5 minutes. When spun or sprayed onto a single wafer, the wafer may be exposed to the etchant for about 30 to about 90 seconds. The etchant then may be removed from the semiconductor device by a clean rinse using a rinse solution comprising, for example, deionized water (step 56).

The following non-limiting post-contact opening etchant formulations set forth hereinbelow illustrate various embodiments of the present invention. Each etchant is formed at room temperature by bubbling gaseous hydrogen fluoride through an aprotic solvent carrier. A fluoride-dissociation modulating agent then is added and the mixture is blended for a time sufficient to form a homogeneous etchant. All percentages are in weight percent (wt. %) of the total etchant.

| | | Fluoride- | |
|---|---|---|---|
| | | Dissociation | |
| | | Modulating Agent | Aprotic Solvent |
| Formulation | HF (wt %) | (wt %) | Carrier (wt %) |
| Formulation 1 | 0.01 | 0.015 pyridine | 99.975 propylene |
| | | | carbonate |
| Formulation 2 | 0.01 | 0.25 pyridine | 99.74 propylene |
| | | | carbonate |
| Formulation 3 | 0.03 | 0.05 hexamine | 99.92 propylene |
| | | | carbonate |
| Formulation 4 | 0.005 | 0.005 hexamine | 99.99 propylene |
| | | | carbonate |
| Formulation 5 | 0.01 | 1 pyridine | 98.99 propylene |
| | | | carbonate |

Accordingly, post-contact opening etchants for post-contact etch cleans have been provided. The post-contact opening etchants, which comprise hydrogen fluoride, a fluoride-dissociation modulating agent, and, optionally, an aprotic solvent carrier, are provided for the removal of residual oxide and organic residues that form on polycrystalline silicon gate electrodes and other silicon-comprising surfaces of semiconductor devices after formation of a contact opening through one or more impurity-doped insulating materials. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A post-contact opening etchant comprising:
anhydrous hydrogen fluoride; and
a fluoride-dissociation modulating agent.

2. The post-contact opening etchant of claim 1, wherein the fluoride-dissociation modulating agent is a secondary organic sulfur-comprising material, a tertiary organic phosphorous-comprising material, or a tertiary organic amine.

3. The post-contact opening etchant of claim 2, wherein the tertiary organic amine comprises a material selected from the group consisting of pyridine, hexamine, triethylamine, trimethylamine, tributylamine, 1,4-diazabicyclo[2.2.2]octane (DABCO), quinuclidine, 1,5-diazabicyclo[4.3.0] non-5-ene (DBN), N-methyl piperidine, N-ethyl piperidine, N-methyl pyrrole, N-ethyl pyrrole, quinoline, pyrimidine, sec-butyldiethylamine, N,N-dimethyl-4-methylaniline, pyrazine, cinnoline, phtalazine, quinazoline, quinoxaline, and mixtures thereof.

4. The post-contact opening etchant of claim 1, further comprising an aprotic solvent carrier.

5. The post-contact opening etchant of claim 4, wherein the aprotic solvent carrier comprises a material selected from the group consisting of propylene carbonate, gamma-butyrolacetone, N-methyl-2-pyrrolidone, ethylene carbonate, butylene carbonate, propylene glycol, ethyl lactate, N,N-dimethylacetamide, monomethyl ether acetate, dimethyl sulfoxide, and mixtures thereof.

6. The post-contact opening etchant of claim 4, wherein the fluoride-dissociation modulating agent comprises pyridine and the aprotic solvent carrier comprises propylene carbonate.

7. The post-contact opening etchant of claim 4, wherein the fluoride-dissociation modulating agent comprises hexamine and the aprotic solvent carrier comprises propylene carbonate.

8. The post-contact opening etchant of claim 4, wherein the fluoride-dissociation modulating agent is present in an amount no greater than about 10 weight percent of the post-contact opening etchant.

9. The post-contact opening etchant of claim 1, wherein the anhydrous hydrogen fluoride is present in an amount no greater than about 5 weight percent of the post-contact opening etchant.

10. The post-contact opening etchant of claim 1, further comprising a functional additive.

11. The post-contact opening etchant of claim 10, wherein the functional additive is a surfactant.

12. The post-contact opening etchant of claim 10, wherein the functional additive comprises a material selected from the group consisting of ammonium fluoride, tetramethylammonium fluoride, tetrabutylammonium fluoride, tetraethylammonium fluoride, benzyltrimethylammonium fluoride, ammonium bifluoride, and mixtures thereof.

13. A method for fabricating a post-contact opening etchant, the method comprising the steps of:
providing an anhydrous hydrogen fluoride;
combining the anhydrous hydrogen fluoride and a fluoride-dissociation modulating agent; and
mixing the anhydrous hydrogen fluoride and the fluoride-dissociation modulating agent to form a homogeneous mixture.

14. The method of claim 13, further comprising the step of combining the anhydrous hydrogen fluoride with an aprotic solvent carrier before, during, or after the step of combining the anhydrous hydrogen fluoride and a fluoride-dissociation modulating agent.

15. The method of claim 14, wherein the step of combining the anhydrous hydrogen fluoride with an aprotic solvent carrier comprises the step of providing an aprotic solvent carrier comprising a material selected from the group consisting of propylene carbonate, gamma-butyrolacetone, N-methyl-2-pyrrolidone, ethylene carbonate, butylene carbonate, propylene glycol, ethyl lactate, N,N-dimethylacetamide, monomethyl ether acetate, dimethyl sulfoxide, and mixtures thereof.

16. The method of claim 14, wherein the step of combining the anhydrous hydrogen fluoride with an aprotic solvent carrier comprise the step of bubbling the anhydrous hydrogen fluoride through the aprotic solvent carrier.

17. The method of claim 14, wherein the step of combining the anhydrous hydrogen fluoride and a fluoride-dissociation modulating agent comprises the step of providing the fluoride-dissociation modulating agent so that it is present in an amount no greater than about 10 weight percent of the post-contact opening etchant.

18. The method of claim 13, wherein the step of providing an anhydrous hydrogen fluoride comprises providing the anhydrous hydrogen fluoride so that it is present in an amount no greater than about 5 weight percent of the post-contact opening etchant.

19. The method of claim 13, wherein the step of providing the anhydrous hydrogen fluoride comprise the step of providing the anhydrous hydrogen fluoride as a gas, as a liquefied gas, or as a mixture of a gas and a liquefied gas.

20. The method of claim 13, wherein the step of combining the anhydrous hydrogen fluoride and a fluoride-dissociation modulating agent comprises the step of combining the anhydrous hydrogen fluoride with a secondary organic sulfur-comprising material, a tertiary organic phosphorous-comprising material, or a tertiary organic amine.

21. The method of claim 20, wherein the step of combining the anhydrous hydrogen fluoride and a tertiary organic amine comprises the step of combining the anhydrous hydrogen fluoride with an amine comprising a material selected from the group consisting of pyridine, hexamine, triethylamine, trimethylamine, tributylamine, 1,4, diazabicyclo[2.2.2]octane (DABCO), quinuclidine, 1,5-diazabicyclo[4.3.0] non-5-ene (DBN), N-methyl piperidine, N-ethyl piperidine, N-methyl pyrrole, N-ethyl pyrrole, quinoline, pyrimidine, sec-butyldiethylamine, N,N-dimethyl-4-methylaniline, pyrazine, cinnoline, phtalazine, quinazoline, quinoxaline, and mixtures thereof.

22. The method of claim 13, further comprising the step of adding a functional additive to the anhydrous hydrogen fluoride before, during, or after the step of combining the anhydrous hydrogen fluoride and a fluoride-dissociation modulating agent.

23. The method of claim 22, wherein the step of adding a functional additive comprises the step of adding a surfactant.

24. The method of claim 22, wherein the step of adding a functional additive comprises the step of adding a functional additive comprising a material selected from the group consisting of ammonium fluoride, tetramethylammonium fluoride, tetrabutylammonium fluoride, tetraethylammonium fluoride, benzyltrimethylammonium fluoride, ammonium bifluoride, and mixtures thereof.

25. The method of claim 13, wherein the step of mixing is performed during the step of combining.

26. A method for cleaning a silicon-comprising surface of a semiconductor device, the method comprising the steps of:
applying an etchant to the silicon-comprising surface, wherein the etchant comprises anhydrous hydrogen fluoride and a fluoride-dissociation modulating agent;
exposing the silicon-comprising surface to the etchant for a predetermined time period; and
removing the etchant from the silicon-comprising surface.

27. The method of claim 26, wherein the step of applying an etchant comprises applying the etchant wherein the etchant comprises anhydrous hydrogen fluoride, an aprotic solvent carrier, and a fluoride-dissociation modulating agent comprising a secondary organic sulfur-comprising material, a tertiary organic phosphorous-comprising material, or a tertiary organic amine.

28. The method of claim 26 wherein the step of applying an etchant comprises the step of applying the etchant wherein the etchant comprises an amine comprising a material selected from the group consisting of pyridine, hexamine, triethylamine, trimethylamine, tributylamine, 1,4-diazabicyclo[2.2.2]octane (DABCO), quinuclidine, 1,5-diazabicyclo[4.3.0] non-5-ene (DBN), N-methyl piperidine, N-ethyl piperidine, N-methyl pyrrole, N-ethyl pyrrole, quinoline, pyrimidine, sec-butyldiethylamine, N,N-dimethyl-4-methylaniline, pyrazine, cinnoline, phtalazine, quinazoline, quinoxaline, and mixtures thereof.
